(19) United States
(12) Patent Application Publication
(10) Pub. No.: US 2010/0098268 A1
(43) Pub. Date: Apr. 22, 2010

(54) HIGH-VOLTAGE OUTPUT AMPLIFIER FOR AUDIO SYSTEMS

(75) Inventor: LANCE WONG, San Francisco, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: NUVOTON TECHNOLOGY CORPORATION, Hsin-Chu (TW)

(21) Appl. No.: 12/253,883

(22) Filed: Oct. 17, 2008

(51) Int. Cl. H03F 3/16; H03F 99/00

(52) U.S. Cl. 381/120; 330/277

(57) ABSTRACT

An amplifier circuit having low-voltage transistors and being configured to operate at a high voltage level is provided. The amplifier circuit includes a driver circuit having a first stage and a second stage connected in series between a power supply and a ground. The driver circuit has a control terminal for receiving a signal for controlling a current flow in the output driver. The amplifier circuit also includes a switch transistor having a drain connected to the power supply, a source connected to the control terminal of the output driver, and a gate. A bias circuit is coupled to the switch transistor. In a first mode of operation, the bias circuit is adapted to turn off the switch transistor, and, in a second mode of operation, the bias circuit is adapted to turn on the switch transistor. The bias circuit is adapted to maintain a gate-to-drain voltage of the switch transistor within a predetermined voltage range.

### CROSS-REFERENCES TO RELATED APPLICATIONS

Not Applicable

### STATEMENT AS TO RIGHTS TO INVENTIONS MADE UNDER FEDERALLY SPONSORED RESEARCH OR DEVELOPMENT

Not Applicable

### REFERENCE TO A “SEQUENCE LISTING,” A TABLE, OR A COMPUTER PROGRAM LISTING APPENDIX SUBMITTED ON A COMPACT DISK

Not Applicable

### BACKGROUND OF THE INVENTION

The present invention relates generally to electronic circuit techniques. More specifically, embodiments of the present invention relate to techniques for amplifier circuits having low-voltage transistors and being operable at high voltage levels.

Amplifier circuits are prevalent in modern electronic devices. An electronic amplifier is a device for increasing the power and/or amplitude of a signal. In particular, power amplifier circuits are used at the output stage of a system to drive an external device, such as a speaker. Power amplifier circuits output stages can be classified as A, B, AB and C for analog designs. This classification is based on the portion of the input signal cycle during which the amplifying device conducts.

A Class A amplifier operates over the whole of the input cycle such that the output signal is an exact magnified replica of the input with no clipping. Class A amplifiers are the usual means of implementing small-signal amplifiers. In a Class A circuit, the amplifying element is biased so the device is always conducting to some extent, and is operated over the most linear portion of its characteristic curve. Because the device is always conducting, even if there is no input at all, power is drawn from the power supply. Accordingly, class A amplifiers tend to be relatively in efficient. For large powers this means very large and expensive power supplies and heat sinking.

Class B amplifiers only amplify half of the input wave cycle. As such they create a large amount of distortion, but their efficiency is greatly improved and is much better than Class A. This is because the amplifying element is switched off altogether half of the time, and so cannot dissipate power. A practical circuit using Class B elements is the complementary pair or “push-pull” arrangement. Here, complementary or quasi-complementary devices are used to each amplify the opposite halves of the input signal, which is then recombined at the output. This arrangement gives excellent efficiency, but can suffer from the drawback that there is a small mismatch at the “joins” between the two halves of the signal. This is called crossover distortion. An improvement is to bias the devices so they are not completely off when they're not in use. This approach is called Class AB operation.

In Class AB operation, each device operates the same way as in Class B over half the waveform, but also conducts a small amount on the other half. As a result, the region where both devices simultaneously are nearly off (the “dead zone”) is reduced. The result is that when the waveforms from the two devices are combined, the crossover is greatly minimized or eliminated altogether. Here the two active elements conduct more than half of the time as a means to reduce the cross-over distortions of Class B amplifiers. In the example of the complementary emitter followers a bias network allows for more or less quiescent current thus providing an operating point somewhere between Class A and Class B.

An audio amplifier is an electronic amplifier that amplifies low-power audio signals to a level suitable for driving loudspeakers. Audio signals generally refer to signals composed primarily of frequencies between 20 hertz to 20,000 hertz, the human range of hearing. An audio output amplifier is often the final stage in a typical audio playback chain. In a typical audio system, the audio amplifier is usually preceded by low power audio amplifiers which perform tasks like pre-amplification, equalization, tone control, mixing/effects, or audio sources like record players, CD players, and cassette players. Important applications include public address systems, theatrical and concert sound reinforcement, and domestic sound systems. The sound card in a personal computer contains several audio amplifiers (depending on number of channels), as does every stereo or home-theatre system. Most audio amplifiers require these low-level inputs to adhere to line levels. While the input signal to an audio amplifier may measure only a few hundred microwatts, its output may be tens, hundreds, or thousands of watts.

Class AB push-pull circuits are the most common design type found in audio power amplifiers. Class AB is widely considered a good compromise for audio amplifiers, since much of the time the music is quiet enough that the signal stays in the “class A” region, where it is amplified with good fidelity, and by definition if passing out of this region, is large enough that the distortion products typical of class B are relatively small. The crossover distortion can be reduced further by using negative feedback. Class B and AB amplifiers are sometimes used for RF linear amplifiers as well. Class B amplifiers are also favored in battery-operated devices, such as transistor radios.

FIG. 1A is a simplified view diagram illustrating an output portion 100 of a conventional audio system. As shown in Figure, an audio frequency signal 102 enters an amplifier 104, which amplifies the signal and drives a speaker 108. A schematic diagram of 100 is shown in FIG. 1B, in which a preamplifier 105 id followed by a CMOS output driver circuit that includes a PMOS driver device 106 and an NMOS driver device 107. The speaker 108 is shown as an equivalent ohmic load, e.g., an 8 ohm resistance load.

In this specific example, the class AB amplifier 105 is used for driving the speaker 108. During normal operation, the class AB amplifier delivers a large output current that is delivered to the small ohmic speaker load 108, as shown in FIG. 2A.

In audio applications, it is often desirable to produce higher output volume in an audio system. This requirement can be met, for example, by increasing the driving capability of an output amplifier. However, high-voltage amplifiers having high-voltage semiconductor devices can be expensive. The manufacturing and testing processes for high-voltage semiconductor devices and circuits can be much more costly than those for low-voltage devices and circuit.

Therefore, amplifiers having low-voltage devices but operable at higher voltage levels are desirable.

### BRIEF SUMMARY OF THE INVENTION

In audio applications, it is often desirable to produce higher output volume in an audio system. This requirement can be met, for example, by increasing the driving capability of an output amplifier. However, high-voltage amplifiers having high-voltage semiconductor devices can be expensive. The manufacturing and testing processes for high-voltage semiconductor devices and circuits can be much more costly than those for low-voltage devices and circuit. Therefore amplifiers having low-voltage devices but operable at higher voltage levels are desirable.

The present invention relates generally to electronic circuit techniques. More specifically, embodiments of the present invention relate to techniques for amplifier circuits operable at a high-voltage level using low-voltage transistors. Such amplifier circuits can deliver more output power and can be built using lower cost manufacturing methods for low-voltage devices. In embodiments of the invention, various bias circuits are utilized to prevent low-voltage devices from exposure to high voltages. For example, an output driver circuit can have bias transistors coupled in series with driver transistors. Additionally, a bias circuit is configured for biasing a power-down transistor such that the power-down transistor can operate in a low-voltage range. The power-down transistor is configured to turn off a driver transistor in the output driver circuit and not interfere with the driver circuit during normal operation. Merely by way of example, the invention has been applied to an integrated circuit including an audio power amplifier having low-voltage devices designed for operating with a high-voltage power supply. But it would be recognized that the invention has a much broader range of applicability. For example, techniques provided by embodiments of the present invention can also be used in any circuit having low-voltage devices and configured to operate at a high voltage level.

In embodiments of the present invention, an amplifier circuit is provided for driving an external load, e.g., a speaker in an audio system. In some embodiments, the amplifier can include low-voltage transistors, but can operate with a high-voltage power supply. In an embodiment, the amplifier includes an output driver circuit that has a first PMOS transistor, a second PMOS transistor, a first NMOS transistor, and a second NMOS transistor connected in series between the power supply and a electrical ground. A gate of the second PMOS transistor is biased at a first reference voltage, and a gate of the first NMOS transistor is biased at a second reference voltage. A switch NMOS transistor has a drain connected to the power supply, a source connected to a gate of the first PMOS transistor, and a gate. In an embodiment, the switch NMOS transistor may have a threshold voltage of approximately 0V. In other embodiments, the switch NMOS transistor can have a positive non-zero threshold voltage. The amplifier circuit also includes a bias circuit coupled to the switch NMOS transistor and being adapted to maintain a gate-to-drain voltage of the switch NMOS transistor within a predetermined voltage range, in a first mode of operation the bias circuit being adapted to turn off the switch NMOS transistor, and in a second mode of operation the bias circuit being adapted to turn on the switch NMOS transistor. In the amplifier, the predetermined voltage range is less than a voltage range between the power supply and a electrical ground. That is, the NMOS switch transistor can be prevented from exposure to the full voltage range of the high voltage power supply.

In embodiments of the above amplifier, the bias circuit is configured to turned off in the second mode of operation to maintain substantially no current flow in the bias circuit. In a specific embodiment, the second PMOS transistor is adapted to limit a drain of the first PMOS transistor in a voltage range approximately between the high-voltage and the first reference voltage. In an embodiment, the first NMOS transistor is adapted to limit a drain of the second NMOS transistor in a voltage range approximately between the first reference voltage and the potential of the electrical ground. In an embodiment, the amplifier further includes a first diode divider circuit for providing the first reference voltage. In a specific embodiment, the bias circuit includes a resistive divider and a first and a second bias NMOS transistors connected in series. In another embodiment, the second bias NMOS transistor of the bias circuit is configured to turn off in the second mode of operation to maintain substantially no current flow in the bias circuit. In an embodiment, the bias circuit comprises a first resistor and a second resistor connected at an internal node that is connected to the gate of the switch NMOS transistor, the resistances of the first and the second resistors being selected such that the internal node is biased at the predetermined gate voltage.

In some embodiment, the amplifier may be operable with a 5V power supply. In a specific embodiment, the voltage of the power supply is approximately 5 V, and the ground potential is approximately 0 V. In an embodiment the predetermined range of voltage is approximately 3 V. In an embodiment, the first reference voltage is approximately 2 V and the second reference voltage is approximately 3.3 V.

In another aspect, the present invention relates to an audio system. In an embodiment the audio system includes an input for receiving an audio frequency input signal and an amplifier circuit coupled to the input for receiving the audio frequency input signal. The amplifier circuit includes an output driver that a first stage and a second stage connected in series between a power supply and a ground. The output driver also includes a control terminal for receiving a signal for controlling a current flow in the output driver. The audio system also includes a switch transistor which has a drain connected to the power supply, a source connected to the control terminal of the output driver, and a gate. In an embodiment, the switch transistor may have a threshold voltage of approximately 0V. In other embodiments, the switch transistor can have a positive non-zero threshold voltage. The audio system also includes a bias circuit coupled to the switch transistor and is adapted to maintain a gate-to-drain voltage of the switch transistor within a predetermined voltage range which is less than a voltage range between the power supply and a electrical ground. In a first mode of operation, the bias circuit is adapted to turn off the switch transistor, and in a second mode of operation the bias circuit is adapted to turn on the switch transistor. The audio system also can include a speaker coupled to the output driver.

In a specific embodiment of the audio system, the bias circuit is configured to turned off in the second mode of operation to maintain substantially no current flow in the bias circuit. In an embodiment, the bias circuit includes a first and a second resistors connected at an internal node that is connected to the gate of the switch transistor.

Many benefits are achieved by way of the present invention over conventional techniques. For example, the present technique provides an easy to use design that that is compatible with conventional integrated circuit design and fabrication process technologies. In certain embodiments, the invention provides techniques for an amplifier circuit having low-voltage transistors but operable at a higher voltage level. In embodiments of the invention, various bias circuits are provided to limit the operating range of the low-voltage devices. In an embodiment, a low-voltage switch device and a bias circuit are provided for turning off an output transistor. Merely as an example, an embodiment of the invention is applied to an output amplifier of an audio system. It is understood, however, the technique can be easily adopted for other applications, such as an output stage of a power amplifier. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1A is a simplified view diagram illustrating an output portion 100 of a conventional audio system.

FIG. 1B is a simplified schematic diagram illustrating an audio amplifier in a conventional audio system;

FIG. 2 is a simplified circuit diagram illustrating an output driver of a conventional audio amplifier;

FIG. 3 is a simplified circuit diagram illustrating an output driver of a conventional audio amplifier including power-down transistors;

FIG. 4 is a simplified circuit diagram illustrating an output driver including a low-voltage power-down switch circuit in an audio amplifier according to an embodiment of the present invention;

FIG. 5 is a simplified schematic diagram illustrating a bias circuit for an output driver circuit according to another embodiment of the present invention; and

FIG. 6 is a simplified schematic diagram illustrating an audio system according to another embodiment of the present invention

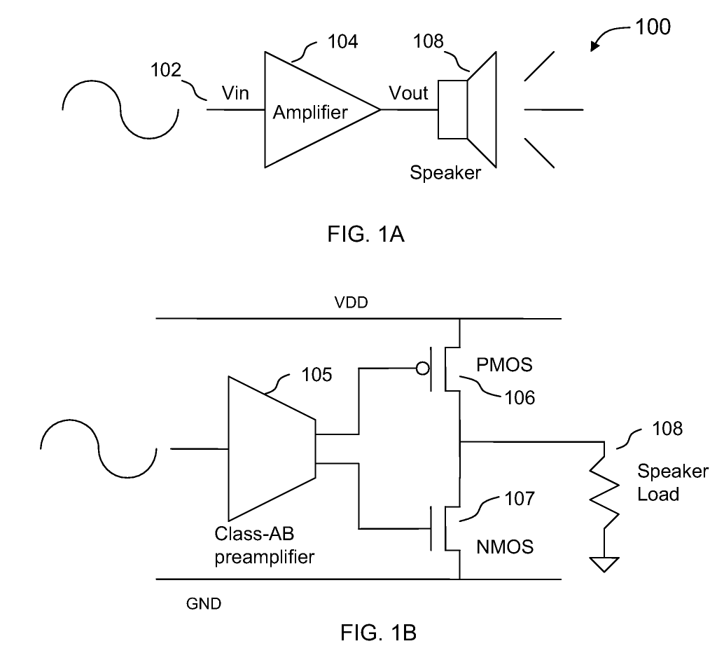

### DETAILED DESCRIPTION OF THE INVENTION

The present invention relates generally to electronic circuit techniques. More specifically, embodiments of the present invention relate to techniques for amplifier circuits operable at high-voltage levels and having low-voltage transistors. Merely by way of example, this invention has been applied to output amplifiers for audio systems. But it would be recognized that the invention has a much broader range of applicability. For example, the invention can be applied to other types of circuits that have low-voltage devices but are operable at higher voltage levels.

In many applications, it is often desirable to increase the driving capability of an output amplifier, for example to obtain higher volume in an audio system. One of the options is to operate the amplifier at a high voltage power supply. But high voltage semiconductor devices require special features that make them more costly. Therefore it is desirable to design an amplifier that including low-voltage devices. Certain design techniques have been employed to do this as illustrated below.

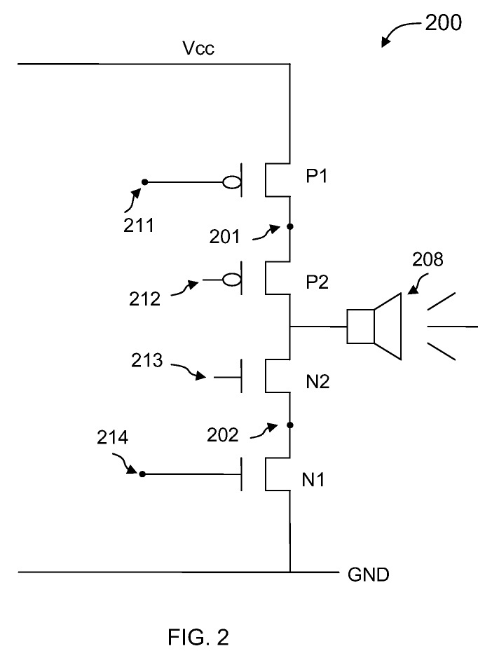

FIG. 2 is a simplified circuit diagram illustrating an output driver of a conventional audio amplifier. As shown, output driver 200 includes PMOS transistors P1 and P2 and NMOS transistors N2 and N1 connected in series between a 5V supply (Vcc) and 0V ground (GND). Transistors P1, P2, N2, and N1 are low-voltage transistors. That is, they are all designed to operate within a lower voltage range, e.g., 3.3V compared to the 5V power supply. In other words, the voltage across any terminals of these transistor should not be allowed to reach much higher than 3.3V or so, e.g., not more than 3.6V. In output driver 200, transistors P1 and N1 are actively involved in signal amplification functions, whereas transistors P2 and N2 provide bias functions that prevent high voltage exposure to the transistors.

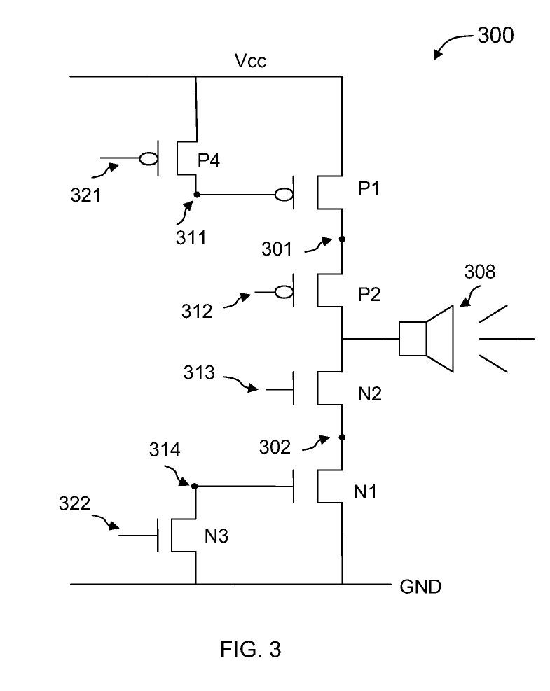

While the circuit of FIG. 2 appears to be able to operate at 5V as an amplifier using low-voltage transistors, problems may occur when the circuit is turned off. Transistor N1 can be turned off by connecting its gate terminal to ground, and transistor P1 can be turned off by connecting its gate terminal to the 5V power supply. This operation can be performed by two transistors operating as switches connecting the gate of N1 to ground and the gate of P1 to the power supply. FIG. 3 illustrates such as configuration, including switch transistors P3 and N3. Note, however, in order to connect the gate terminal of P1 to the power supply, switch transistor P4 needs to be fully turned on. This is often accomplished by connecting the gate terminal of P4 to ground. Under this condition, the gate-to-source voltage of P3 becomes 5V, exceeding the operating range of transistor P3 and may cause damage to transistor P3.

Another convention approach to turn off amplifier circuit 200 is to provide level-shifted logic to control the gate voltages of P1 and N1, respectively. Even though this approach can keep the devices from high voltages, using level-shifted logic tends to increase power consumption.

Therefore, improved techniques are needed for amplifiers having low-voltage transistor and being configured to operate at higher voltage levels.

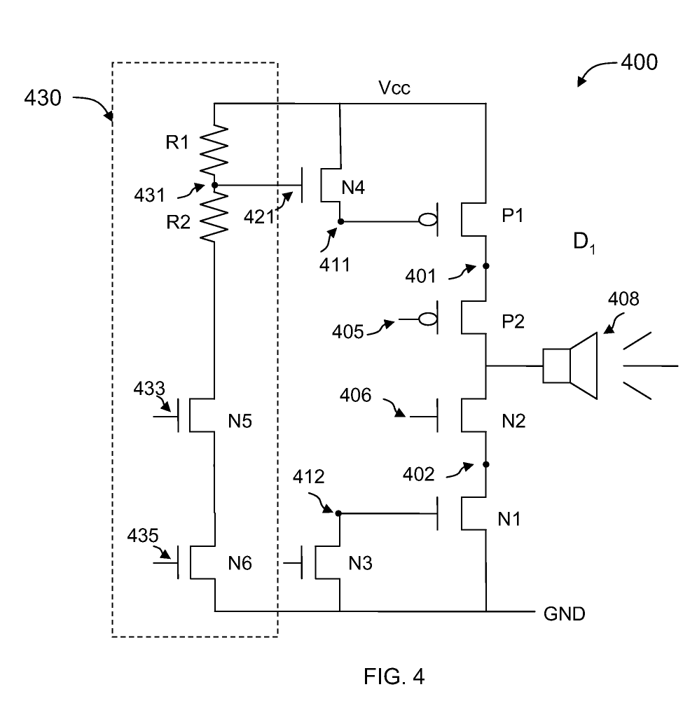

FIG. 4 is a simplified circuit diagram illustrating an output driver 400 including a low-voltage power-down switch circuit in an audio amplifier according to an embodiment of the present invention. As shown, output driver circuit 400 includes PMOS transistors P1 and P2 and NMOS transistors N2 and N1 connected in series between a 5V supply (Vcc) and 0V ground (GND). Transistors P1, P2, N2, and N1 are low-voltage transistors configured to operate within a lower voltage range, e.g., 3.3V compared to the 5V power supply. In output driver 400, transistors P1 and N1 are output driver transistors actively involved in signal amplification function, whereas transistors P2 and N2 are reference bias transistors providing biasing function that prevent high voltage exposure to the transistors.

In a specific embodiment of amplifier 400 in FIG. 4, the gate terminal of PMOS transistor P2 is biased at a first reference voltage of 2V. As a result, the drain terminal 301 of P1, which is also the source terminal of P2 is prevented from dropping below 2V. Therefore, transistor P1 has a source terminal at 5V and drain terminal not lower than 2V. Additionally, the gate terminal of PMOS transistor P1 is allowed to vary in a range of approximately 2V-5V, reflecting a signal received from a previous circuit stage, e.g., a preamplifier. Thus, P1 is configured to operate with the limitation of a 3.3V device. Similarly, the gate terminal of NMOS transistor N2 is biased with a second reference voltage of 3.3V, limiting the drain-to-source voltage drop in N2 to not more than 3.3V. The gate terminal of N1 receives input signal between 0-3V from the previous circuit stage. In FIG. 4, NMOS transistor N1 and PMOS transistor P1 are driver transistors providing the class AB amplification function for amplifier 400.

An embodiment of the present invention provides a power-down circuit for turning off the driver circuit of amplifier 400. As shown in FIG. 4, an NMOS transistor N3 is coupled to the gate terminal 412 of NMOS transistor N1. In the power-down mode, 3.3V can be applied to the gate of N3, turning on N3 and pulling down node 412, thereby turning off NMOS transistor N3. Additionally, a low-voltage NMOS switch transistor N4 is provided that is configured to turn off PMOS transistor P1. A bias circuit is coupled to the low-voltage transistor N4 for maintaining the terminals of N4 in a low voltage range. This bias circuit is also configured so that low-voltage switch transistor N4 does not interfere with the normal operation of the gate terminal 411 of PMOS transistor P1, which receives input signals from a previous circuit stage. In some embodiments of the present invention, NMOS transistor N4 has a threshold voltage of approximately 0V. In a specific embodiment, NMOS transistor N4 can be a native transistor. For example, NMOS transistor N4 can be fabricated in the same process as other NMOS transistors but without the threshold implant. The well doping in the channel region can result in a low threshold voltage close to 0V. In other embodiments, NMOS transistor N4 can have a positive threshold voltage.

In FIG. 4, the drain terminal of NMOS switch transistor N4 is connected to the power supply and a source terminal of NMOS transistor N4 is connected to the gate terminal 411 of PMOS transistor P1. The gate terminal 421 of NMOS transistor N4 is coupled to a bias circuit 430. As shown in FIG. 4, bias circuit 430 includes resistors R1 and R2 and NMOS transistors N5 and N6 connected in series between the power supply Vcc and the ground terminal GND.

According to an embodiment of the present invention, when bias circuit 430 is in an active mode, it is configured to bias the gate terminal 421 of NMOS transistor N4 below 2V. As described above, the gate terminal 411 of PMOS transistor P1 operates in a range of approximately 2-5V, reflecting a signal from a previous circuit stage. Under this condition, N4 is off. Therefore, NMOS transistor N4, as well as bias circuit 430, does not interfere with the normal operation of PMOS transistor P1. In a specific embodiment, the bias condition for bias circuit 430 in active mode can be determined by a ratio of resistance values of resistors R1 and R2, with NMOS transistors N5 and N6 turned on. For example, NMOS transistors N5 and N6 can be turned on with their respective gate terminals 433 and 435 biased at 3.3V. Large resistance values can be selected for R1 and R2 such that the current I1 in the bias circuit 430 is low to reduce the drain-to-source voltage drops in transistors N5 and N6. Moreover, large resistances in R1 and R2 can minimize power consumption in the bias circuit. Additionally, the ratio of R1 and R2 can be selected such that the voltage at node 431 is maintained below the voltage at the gate of PMOS transistor P1, e.g., 2V. In an specific embodiment, the resistance values for R1 and R2 are 460 K ohms and 240 K ohms, respectively.

As described above, in an active mode the bias circuit 430 provides a bias voltage to maintain the gate terminal 421 of NMOS transistor N4 at a predetermined gate voltage such that N4 does not interfere with the normal operation of PMOS transistor P1. As described above, PMOS transistor P4 is configured to receive input signals from a previous circuit stage. In a power-down mode, either N5 or N6 is turned off with a gate bias of 0V. Node 431 of the bias circuit 430, which is also the gate terminal of NMOS switch transistor N4, is pulled to Vcc, turning on N4 and allowing PMOS transistor P1 to be turned off. Additionally, in the power-down mode, bias circuit 430 consumes substantially no standby current, while the low-voltage NMOS switch transistor N4 is prevented from to high-voltage conditions.

Although the above has been shown using a selected group of components for the output drive circuit for an amplifier, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification and more particularly below.

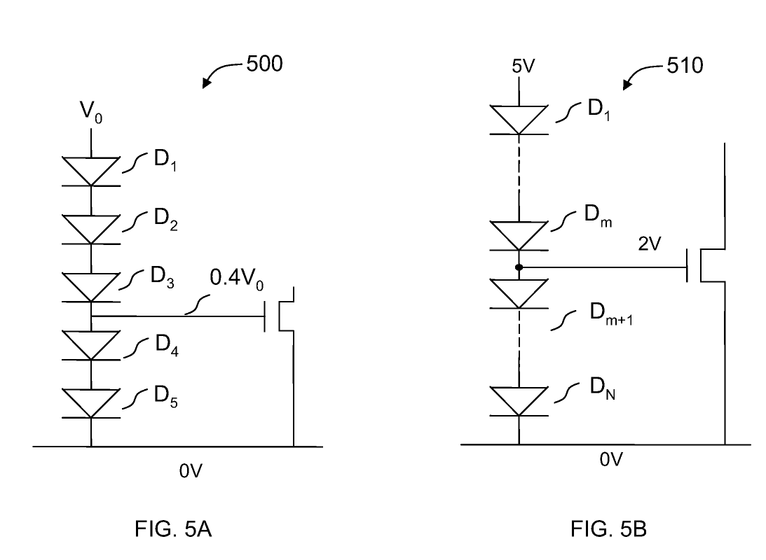

FIGS. 5A and 5B are simplified schematic diagrams illustrating examples of bias circuits for an output driver circuit according to another embodiment of the present invention. The techniques described here can be used for providing various reference voltages in an amplifier circuit such as amplifier 400 of FIG. 4. As shown in FIG. 5A, bias circuit 500 has a plurality serially connected diode devices. In a specific embodiment, these diode devices include a plurality diode devices, namely, a first (D₁), a second (D₂), . . . and a fifth (D₅) diode devices. The first diode device D₁ is coupled to the power supply Vcc, and the 5th diode device D₅ is coupled to a ground potential. FIG. 5B illustrates a more general configuration of the bias circuit, including diode devices D₁, . . . , Dₘ, Dₘ₊₁ . . . D_{N}. Each of these diode devices provides a rectifying function, i.e. allowing current flow in one direction and blocking current flow in the other direction. Each diode device is also characterized by a turn-on voltage. As discussed below, each of these diode devices can be implemented using any rectifying device, such as a p-n junction diode, a diode-connected NMOS transistor, a diode connected PMOS transistor, or a Schottky diode, etc.

In a specific embodiment of bias circuits 500 in FIG. 5A and bias circuit 510 in FIG. 5B, each diode device has a turn-on voltage V_{D} of approximately 0.7 V. The current in each diode is low when the diode is biased at a voltage below the turn-on voltage. Thus, a low current voltage divider can be provided by including by connecting a plurality of diode devices between a first potential and a second potential and deriving a bias voltage from an internal node. In FIG. 5A, a bias voltage of 0.4V₀ is derived from the circuit connected to V₀. Merely as an example, 10 such diode device can be connected between 5V and 0V, and a 2V bias voltage can be taken from the node between the sixth and the seventh diode, as shown in FIG. 5B with m=6 and N=10. The current consumption in the bias circuits is low, since each diode is biased at approximately 0.5V, which is below the turn-on voltage.

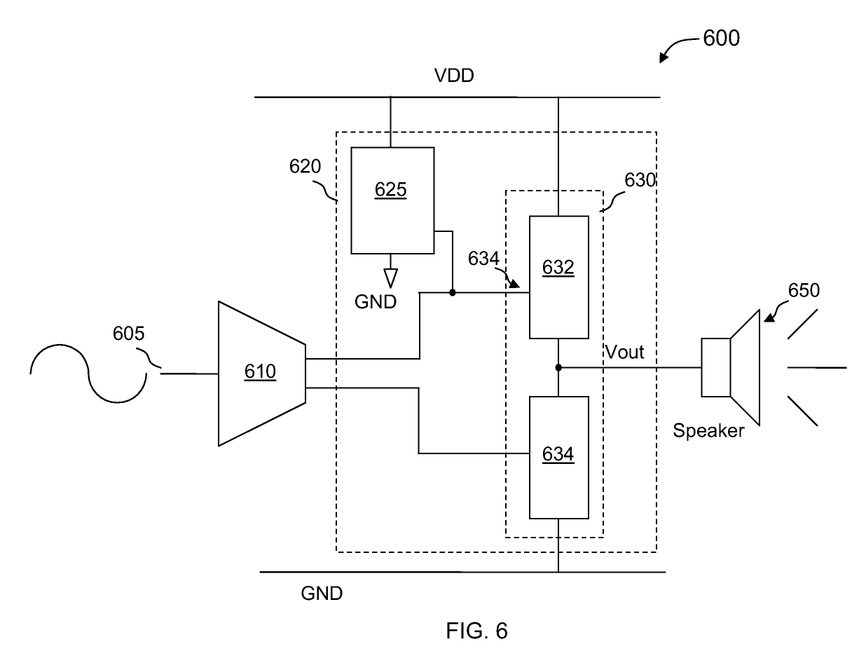

FIG. 6 is a simplified schematic diagram illustrating an audio system 600 according to an embodiment of the present invention. This diagram is merely an example, which should not unduly limit the scope of the claims herein. As shown, audio system 600 includes a preamplifier 610, an output amplifier 620, and a speaker 650. The preamplifier 610 received audio signal 605, which enters into audio system through an input (not shown). The audio signal can also be derived from a previous circuit stage of the audio system. In some embodiments, the audio signal may be processed in other parts of the audio system before being received by preamplifier 610. In an embodiment, preamplifier 610 can be a conventional class AB audio amplifier that receives audio frequency signal 605 and delivers amplified signal to the output amplifier 620.

In an embodiment, output amplifier 620 includes output driver circuit 630 and bias circuit 625. In the specific example shown in FIG. 6, the output driver circuit 630 includes a first stage 632 and a second stage 634. A bias circuit may be coupled to either the first stage 632 or the lower stage 634. In a specific embodiment, output driver circuit 630 may include a CMOS output driver circuit as illustrated in FIG. 4.

In an embodiment, bias circuit 625 provides a bias voltage to a driver device, e.g., the first stage 632. In the example shown in FIG. 6, first stage circuit 632 has a control terminal 634 for controlling a current flow through the device. For example, the control terminal 634 in FIG. 6 can be a gate terminal of a PMOS transistor, such as PMOS transistor P1 in FIG. 4. Bias circuit 625 may include a power-down transistor similar to transistor N5 and a bias circuit block similar to bias circuit 430 discussed above in connection with FIG. 4. In particular, bias circuit 625 is configured for biasing a power-down transistor such that the power-down transistor can operate in a low-voltage range. The power-down transistor is configured to turn off a driver transistor in the first stage 632 in the output driver circuit 630 and not interfere with the driver circuit during normal operation.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as described in the claims.

What is claimed is:

1. An amplifier circuit, comprising:
an output driver circuit including a first PMOS transistor, a second PMOS transistor, a first NMOS transistor, and a second NMOS transistor connected in series between the power supply and a electrical ground, a gate of the second PMOS transistor being biased at a first reference voltage, a gate of the first NMOS transistor being biased at a second reference voltage; and
a switch NMOS transistor having a threshold voltage of approximately 0V, the switch NMOS transistor having a drain connected to the power supply, a source connected to a gate of the first PMOS transistor, and a gate; and
a bias circuit coupled to the switch NMOS transistor and being adapted to maintain a gate-to-drain voltage of the switch NMOS transistor within a predetermined voltage range, in a first mode of operation the bias circuit being adapted to turn off the switch NMOS transistor, and in a second mode of operation the bias circuit being adapted to turn on the switch NMOS transistor,
wherein the predetermined voltage range being less than a voltage range between the power supply and a electrical ground.

2. The amplifier circuit of claim 1 wherein the bias circuit is configured to turned off in the second mode of operation to maintain substantially no current flow in the bias circuit.

3. The amplifier circuit of claim 1 wherein the second PMOS transistor is adapted to limit a drain of the first PMOS transistor in a voltage range approximately between the high-voltage and the first reference voltage.

4. The amplifier circuit of claim 1 wherein the first NMOS transistor is adapted to limit a drain of the second NMOS transistor in a voltage range approximately between the first reference voltage and the potential of the electrical ground.

5. The amplifier circuit of claim 1 further comprising a first diode divider circuit for providing the first reference voltage.

6. The amplifier circuit of claim 1 wherein the bias circuit comprises a resistive divider and a first and a second bias NMOS transistors connected in series.

7. The amplifier circuit of claim 6 wherein the second bias NMOS transistor of the bias circuit is configured to turned off in the second mode of operation to maintain substantially no current flow in the bias circuit.

8. The amplifier circuit of claim 6 wherein the bias circuit comprises a first and a second resistors connected at an internal node that is connected to the gate of the switch NMOS transistor, the resistances of the first and the second resistors being selected such that the internal node is biased at the predetermined gate voltage.

9. The amplifier circuit of claim 6 wherein the voltage of the power supply is approximately 5 V, and the ground potential is approximately 0 V.

10. The amplifier circuit of claim 9 wherein the predetermined range of voltage is approximately 3 V.

11. The amplifier circuit of claim 9 wherein the first reference voltage is approximately 2 V and the second reference voltage is approximately 3.3 V.

12. An amplifier circuit, the amplifier circuit comprising:
a driver circuit, including a first stage and a second stage connected in series between a power supply and a ground, the driver circuit having a control terminal for receiving a signal for controlling a current flow in the output driver;
a switch transistor having a drain connected to the power supply, a source connected to the control terminal of the output driver, and a gate;
a bias circuit coupled to the switch transistor, the bias circuit being adapted to maintain a gate-to-drain voltage of the switch transistor within a predetermined voltage range, in a first mode of operation the bias circuit being adapted to turn off the switch transistor, and in a second mode of operation the bias circuit being adapted to turn on the switch transistor,
wherein the predetermined voltage range being less than a voltage range between the power supply and a electrical ground.

13. The amplifier circuit of claim 12 wherein the bias circuit is configured to turned off in the second mode of operation to maintain substantially no current flow in the bias circuit.

14. The amplifier circuit of claim 12 wherein the bias circuit comprises a resistive divider and a first and a second bias NMOS transistors connected in series.

15. An audio system, comprising:
an input for receiving an audio frequency input signal;
an amplifier circuit coupled to the input for receiving the audio frequency input signal, the amplifier circuit including an output driver having a first stage and a second stage connected in series between a power supply and a ground, the output driver also including a control terminal for receiving a signal for controlling a current flow in the output driver;
a switch transistor having a threshold voltage of approximately 0V, the switch transistor having a drain connected to the power supply, a source connected to the control terminal of the output driver, and a gate;
a bias circuit coupled to the switch transistor and being adapted to maintain a gate-to-drain voltage of the switch transistor within a predetermined voltage range, in a first mode of operation the bias circuit being adapted to turn off the switch transistor, and in a second mode of operation the bias circuit being adapted to turn on the switch transistor,
wherein the predetermined voltage range being less than a voltage range between the power supply and a electrical ground, and
a speaker coupled to the output driver.

16. The audio system of claim 15, wherein the bias circuit is configured to turned off in the second mode of operation to maintain substantially no current flow in the bias circuit.

17. The audio system of claim 15 wherein the bias circuit comprises a first and a second resistors connected at an internal node that is connected to the gate of the switch transistor.

18. An audio system, comprising:
an input for receiving an audio frequency input signal;
an amplifier circuit coupled to the input for receiving the audio frequency input signal, the amplifier circuit including a first stage and a second stage connected in series between a power supply and a ground, the output driver having an output node and a control terminal for receiving a signal for controlling a current flow to the output node;
a switch transistor having a drain connected to the power supply, a source connected to the control terminal of the output driver, and a gate;
a bias circuit coupled to the switch transistor, the bias circuit being adapted to maintain a gate-to-drain voltage of the switch transistor within a predetermined voltage range, in a first mode of operation the bias circuit being adapted to turn off the switch transistor, and in a second mode of operation the bias circuit being adapted to turn on the switch transistor, wherein the predetermined voltage range being less than a voltage range between the power supply and an electrical ground, and
a speaker coupled to the output driver.

19. The audio system of claim 18, wherein the bias circuit is configured to turned off in the second mode of operation to maintain substantially no current flow in the bias circuit.

20. The audio system of claim 18 wherein the bias circuit comprises a first and a second resistors connected at an internal node that is connected to the gate of the switch transistor.
